(19) United States
(12) Patent Application Publication
(10) Pub. No.: US 2019/0090347 A1
(43) Pub. Date: Mar. 21, 2019

(54) WIRING BOARD AND PLANAR TRANSFORMER

(71) Applicant: NGK SPARK PLUG CO., LTD., Nagoya (JP)

(72) Inventors: Masahito MORITA, Yokohama-shi (JP); Kenji SUZUKI, Ichinomiya-shi (JP)

(21) Appl. No.: 16/127,382

(22) Filed: Sep. 11, 2018

(30) Foreign Application Priority Data
Sep. 15, 2017 (JP) 2017-177556

(51) Int. Cl. H05K 1/16; H01F 30/06; H05K 1/18; H05K 1/03; H05K 3/38; H05K 3/46

(52) U.S. Cl. CPC H05K 1/165; H01F 30/06; H05K 1/18; H05K 2201/0175; H05K 3/38; H05K 3/4667; H05K 1/0306

(57) ABSTRACT

Disclosed is a wiring board having a plurality of insulating layers and at least one wiring layer each formed between adjacent two of the plurality of insulating layers such that, when a cross section of the wiring layer is taken in parallel to a thickness direction, at least one corner portion of the cross section of the wiring layer is rounded.

### FIELD OF THE INVENTION

The present invention relates to a wiring board and a planar transformer.

### BACKGROUND OF THE INVENTION

There is known a method for manufacturing a multilayer wiring board in which a plurality of insulating layers and a plurality of wiring layers are alternately laminated together, including a process of forming the wiring layers by printing a metal paste on the insulating layers and firing the printed paste. In this method, however, the wiring layers cannot ensure their sufficient thickness so that there would be a limit to the decrease in resistance of the wiring layers.

On the other hand, there is known a process for forming a wiring layer by bonding a metal foil to an insulating layer (see, for example, Japanese Laid-Open Patent Publication No. H11-329842).

### SUMMARY OF THE INVENTION

In the above-mentioned multilayer wiring board, the insulating layer may be damaged by contact with a peripheral corner portion of the wiring layer. This damage can become a starting point of the occurrence of a crack in the insulating layer.

In view of the foregoing, it is an object of the present invention to provide a wiring board capable of preventing an insulating layer from being damaged by contact with a wiring layer. It is also an object of the present invention to provide a planar transformer with such a wiring board.

In accordance with a first aspect of the present invention, there is provided a wiring board, comprising:
a plurality of insulating layers; and
at least one wiring layer each located between adjacent two of the plurality of insulating layers,
wherein, when a cross section of the at least one wiring layer is taken in parallel to a thickness direction, at least one corner portion of the cross section of the at least one wiring layer is rounded.

In this configuration, the peripheral corner portion of the wiring layer is rounded. It is consequently possible to, even when the peripheral corner portion of the wiring layer is brought into contact with the insulating layer, prevent the peripheral corner portion of the wiring layer from causing damage to the insulating layer and thereby possible to suppress the occurrence of a crack in the insulating layer.

In accordance with a second aspect of the present invention, there is provided a wiring board as described above, wherein, in the cross section, a dimension of the rounded corner portion in the thickness direction is 30% or less of an average thickness of the at least one wiring layer.

In this configuration, it is possible to effectively prevent the wiring layer from causing damage to the insulating layer adjacent thereto, while suppressing a deterioration in the strength of the wiring layer.

In accordance with a third aspect of the present invention, there is provided a wiring board as described above, wherein all of corner portions of the cross section of the at least one wiring layer are rounded.

In this configuration, it is possible to simultaneously prevent the wiring layer from causing damage to adjacent two of the insulating layers.

In accordance with a fourth aspect of the present invention, there is provided a wiring board as described above, wherein the at least one wiring layer includes a plurality of wiring layers, and wherein the plurality of insulating layers and the plurality of wiring layers are alternately laminated in the thickness direction.

In this configuration, it is possible to provide the multilayer wiring board of high quality with the plurality of wiring layers.

In accordance with a fifth aspect of the present invention, there is provided a wiring board as described above, wherein the at least one wiring layer is not fixed to any of the plurality of insulating layers adjacent thereto. When the wiring layer and the insulating layers expand or contract in accordance with temperature changes, there arises a difference in deformation amount between the wiring layer and the insulating layers due to a difference in thermal expansion coefficient. In this configuration, however, such a deformation amount difference can be absorbed by individual displacements of the wiring layer and the insulating layers. It is thus possible to reduce stress caused between the insulating layers and the wiring layer and suppress the occurrence of a defect such as crack in the insulating layers.

In accordance with a sixth aspect of the present invention, there is provided a wiring board as described above, wherein the plurality of insulating layers contain a ceramic material as a main component.

In this configuration, it is possible to improve the flatness of the insulating layers so that the wiring layer can be arranged at high density over the insulating layer. It is also possible to ensure the high insulation properties of the insulating layers.

In accordance with a seventh aspect of the present invention, there is provided a planer transformer comprising the above-described wiring board.

The other objects and features of the present invention will also become understood from the following description.

### BRIEF DESCRIPTION OF DRAWINGS

FIG. 1 is a schematic cross-sectional view of a wiring board, as taken in parallel to a thickness direction thereof, according to one embodiment of the present invention.

FIG. 2 is a schematic cross-sectional view of a part of the wiring board of FIG. 1 in the vicinity of connection conductors.

FIG. 3 is a flowchart of a method for manufacturing the wiring board of FIG. 1.

FIG. 4 is a schematic cross-sectional view of a wiring board, as taken in parallel to a thickness direction thereof, according to another embodiment of the present invention.

### DESCRIPTION OF EMBODIMENTS

Hereinafter, exemplary embodiments of the present invention will be described below with reference to the drawings.

### 1. Embodiment

[1-1. Structure of Wiring Board]

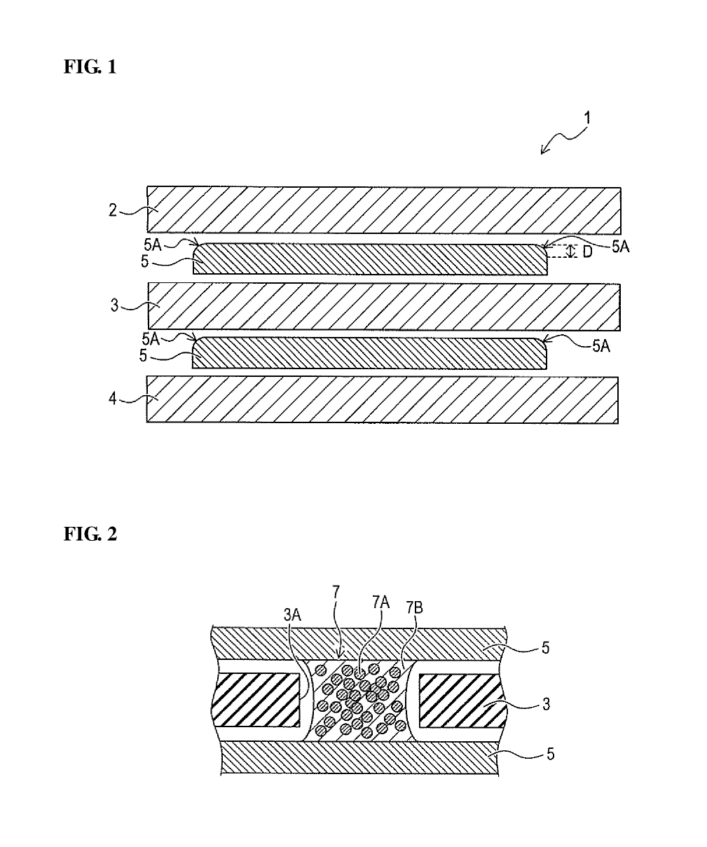

As shown in FIG. 1, a wiring board 1 according to one embodiment of the present invention has a plurality of insulating layers (a first insulating layer 2, a second insulating layer 3 and a third insulating layer 4), a plurality of wiring layers 5 and at least one connection conductor 7 (see also FIG. 2) connecting the plurality of wiring layers 5.

Although the wiring board 1 is illustrated as having a multilayer structure with three insulating layers 2, 3 and 4 and two wiring layers 5 in the present embodiment, the number of insulating layers 2, 3 and 4 and the number of wiring layers 5 are not limited to these numbers. The present invention is applicable to the wiring board 1 as long as the wiring board 1 has two or more insulating layers and at least one wiring layer.

Depending on the pattern design of the wiring layers 5, the wiring board 1 can be used for various applications such as a transformer, an insulating gate bipolar transistor (IGBT), a light-emitting diode (LED) illumination device, a power transistor, a motor and the like. The wiring board 1 can particularly suitably be used for high-voltage, high-current applications because of the ease of increasing the thickness of the wiring layers 5.

<Insulating Layers>

Each of the first, second and third insulating layers 2, 3 and 4 has two opposing front and back surfaces (i.e. upper and lower surfaces in FIG. 1) and contains a ceramic material as a main component. Herein, the term “main component” refers to a component contained in an amount of 80 mass % or more. Examples of the ceramic material contained in the insulating layers 2, 3 and 4 are alumina, beryllia, aluminum nitride, boron nitride, silicon nitride, silicon carbide, LTCC (Low Temperature Co-fired Ceramic) and the like. These ceramic materials can be used solely or in combination of two or more thereof.

The first, second and third insulating layers 2, 3 and 4 are arranged in this order in a thickness direction. As shown in FIG. 2, at least one through hole 3A is formed though second insulating layer 3 in the thickness direction. This through hole 3A is a via hole in which the connection conductor 7 (as a so-called via conductor) is disposed to establish electrical connection between the wiring layers 5 in the thickness direction.

<Wiring Layers>

Each of the wiring layers 5 has two opposing front and back surfaces (i.e. upper and lower surfaces in FIG. 1). The wiring layers 5 shows electrical conductivity and each contains a metal material as a main component. Examples of the metal material contained in the wiring layers 5 are copper, aluminum, silver, gold, platinum, nickel, titanium, chromium, molybdenum, tungsten, alloys thereof and the like. Among others, copper is preferred in terms of cost, electrical conductivity, thermal conductivity and strength. A copper foil or copper plate (sheet) can suitably be used as the wiring layer 5.

As shown in FIG. 1, the plurality of wiring layers 5 are each located between the first insulating layer 2 and the second insulating layer 3 and between the second insulating layer 3 and the third insulating layer 4. Namely, the plurality of insulating layers 2, 3, 4 and the plurality of wiring layers 5 are alternately laminated in the thickness direction, with the front and back surfaces of each of the wiring layers 5 being opposed to and facing any of the insulating layers 2, 3, 4 adjacent thereto.

Each of the wiring layers 5 has such a shape that, when an arbitrary cross section of the wiring layer 5 is taken in parallel to the thickness direction, two front side corner portions 5A of the cross section are rounded as shown in FIG. 1 in the present embodiment. More specifically, the peripheral edge of the front surface of the wiring layer 5 (which is opposed to the back surface of the first wiring layer 2 in the case of the wiring layer 5 located between the first and second insulating layers 2 and 3; and which is opposed to the back surface of the second insulating layer 3 in the case of the wiring layer 5 located between the second and third insulating layers 3 and 4) is rounded.

In the cross section of the wiring layer 5, the two rounded corner portions 5A have a smoothly curved outline to continuously connect the front surface to side surfaces of the wiring layer 5. In FIG. 1, the cross-sectional outline of the rounded corner portion 5A is circular arc. However, the cross-sectional outline of the rounded corner portion 5A is not necessarily circular arc and can be any curve with no discontinuity. It is feasible to round the corner portions 5A by, for example, performing punching, etching, grinding, discharge machining etc. on the metal foil or metal plate as the material of the wiring layer 5.

In the present embodiment, the range of formation of the rounded corner portions 5A in the thickness direction, that is, a dimension D of the rounded corner portions 5A in the thickness direction is 30% or less of an average thickness of the wiring layer 5. The term “average thickness” used herein refers to an average of values of the thickness as measured at ten separate points in the plane direction.

Further, each of the wiring layers 5 is apart from and is not fixed to any of the insulating layers 2, 3, 4 adjacent thereto in the present embodiment. In other words, each wiring layer 5 does not have a fixed area and have only a non-fixed area assuming that: the fixed area is an area where the wiring layer 5 is fixed to the insulating layers 2, 3, 4 adjacent thereto; and the non-fixed area is an area where the wiring layer 5 is not fixed to the insulating layers 2, 3, 4 adjacent thereto. It is noted that, since the connection conductor 7 is not joined to the insulating layer 3 as will be explained later in the present embodiment, the junction of the wiring layer 5 to the connection conductor 7 is included in the non-fixed area. Thus, the wiring layers 5 are respectively individually displaceable relative to the insulating layers 2, 3, 4 adjacent thereto.

Alternatively, each of the wring layers 5 may be in contact with any of the insulating layers 2, 3, 4 adjacent thereto as long as the wiring layers 5 are respectively individually displaceable relative to the insulating layers 2, 3, 4 adjacent thereto.

<Connection Conductors>

As shown in FIG. 2, the connection conductor 7 is disposed in the through holes 3A of the second insulating layer 3. This connection conductor 7 serves as a so-called via conductor to electrically connect two wiring layers 5 as mentioned above. The connection conductor 7 is joined to two wiring layers 5, but is not joined to the second insulating layer 3.

In the present embodiment, the connection conductor 7 has a metal granular body 7A and a junction part 7B as shown in FIG. 2.

The metal granular body 7A is in the form of an agglomerate of metal granules (particles) and is arranged within the through hole 3A of the second insulating layer 3 so as to electrically connect two wiring layers 5 through the junction part 7B. There is no particular limitation on the material of the metal granular body 7A. The metal granular body 7A can be made of the same metal material as that of the wiring layers 5. It is preferable that the material of the metal granular body 7A is the same as the main component of the wiring layers 5. The use of such a material is effective to reduce stress caused between the connection conductor 7 and the two wiring layers 5 due to temperature changes. There is also no particular limitation on the shape of the metal granules (particles) as the constituents of the metal granular body 7A. The metal granules of the metal granular body 7A can be spherical, polyhedral or the like. Further, the metal granules of the metal granular body 7A are not necessarily of the same shape and size and can be of different shapes and sizes.

The metal granular body 7A is held in the through hole 3A by the junction part 7B. In the through hole 3A, some of the metal granules of the metal granular body 7A may be in contact with each other. Some of the metal granules of the metal granular body 7A may protrude through the junction part 7B or may be in contact with the two wiring layers 5.

The junction part 7B shows electrical conductivity to electrically connect the metal granular body 7A to the two wiring layers 5. As the material of the junction part 7B, there can be used a metal brazing material such as silver-copper alloy, a solder material such as tin-silver-copper alloy, or the like.

As shown in FIG. 2, the junction part 7B is joined to outer surfaces of the metal granules of the metal granular body 7A and to the two wiring layers 5 so that the metal granular body 7A is joined and electrically connected to the two wiring layers 5 through the junction part 7B. On the other hand, the junction part 7B is not joined to the second insulating layer 3, i.e., not fixed to an inner wall of the through hole 3A of the second insulating layer 3. There is space left between the connection conductor 7 and the inner wall of the through hole 3A of the second insulating layer 3.

It is preferable that, in one connector conductor 7, the total volume of the metal granular body 7A is smaller than the total volume of the junction part 7B. In terms of reliability in electrical connection, it is preferable that the metal granules of the metal granular body 7A are dispersed in the junction part 7B.

[1-2. Manufacturing Method of Wiring Board]

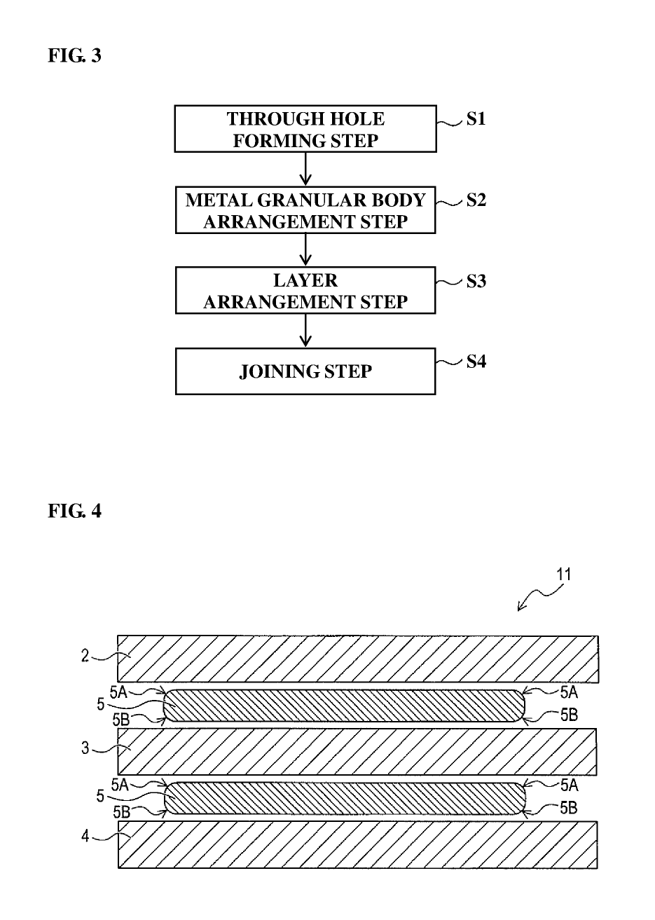

The above-structure wiring board 1 can be manufactured through the following through hole forming step S1, metal granular body arrangement step S2, layer arrangement step S3 and joining step S4 as shown in FIG. 3.

<Through Hole Forming Step>

In the through hole forming step S1, the plurality of insulating layers 2, 3 and 4 are provided; and the through hole 3A is formed through the insulating layer 3 in the thickness direction. For example, the through hole forming step S1 can be performed as follows. A slurry is first prepared by mixing a powder of ceramic material with an organic binder, a solvent and an additive such as plasticizer. This slurry is formed into a sheet (substrate) shape by a known technique, thereby yielding a plurality of substrate-shaped green ceramic bodies (called “ceramic green sheets”). The second insulating layer 3 with the through hole 3A is formed by e.g. punching the through hole 3A through the ceramic green sheet and then firing the ceramic green sheet. The first and third insulating layers 2 and 4 are formed by firing the ceramic green sheets without punching.

<Metal Granular Body Arrangement Step>

In the metal granular body arrangement step S2, the metal granular body 7A and the junction part 7B are arranged in the through hole 3A of the second insulating layer 3. More specifically, a paste in which the material of the metal granular body 7A and the metal brazing material or solder material as the material of the junction part 7B have been mixed with a solvent is put into the through hole 3A by means of a dispenser etc. It is alternatively feasible to arrange the metal granular body 7A in the though hole 3A in a state where the metal granular body 7A and the junction part 7B are joined as shown in FIG. 2 or arrange the metal granular body 7A in the through hole 3A in a state where the respective solid metal granules of the metal glandular body 7A are coated with e.g. the metal brazing material of the junction part 7B.

<Layer Arrangement Step>

In the layer arrangement step S3, the plurality of insulating layers 2, 3 and 4 (including the second insulating layer 3 in which the metal granular body 7A has been arranged along with the junction part 7B) and the plurality of wiring layers 5 are alternately laminated to one another. Before the lamination of the wiring layers 5, the peripheral corner portions of the wiring layers 5 are rounded by performing punching, etching, grinding, discharge machining etc. on the metal foil or metal plate as the material of the wiring layer 5.

The layer arrangement step S3 may be performed before or in parallel with the metal granular body arrangement step S2. For example, it is feasible to arrange one wiring layer 5 on the back surface side of the second insulating layer 3, arrange the metal granular body 7A and the junction part 7B in the though hole 3A of the second insulating layer 3, and then, arrange another wiring layer 5 on the front surface side of the second insulating layer 3.

<Joining Step>

In the joining step S4, the metal granular body 7A is joined to the two wiring layers 5 by heating the laminated layer assembly obtained in the layer arrangement step S3 to thereby melt the junction part 7B, and then, solidifying the molten material. The connection conductor 7 is formed by this step operation.

[1-3. Effects]

In the present embodiment, the following effects are obtained.

(1a) As mentioned above, the peripheral corner portions 5A of the wiring layer 5 are rounded. It is consequently possible to, even when the periphral corner portion 5A of the wiring layer 5 is brought into contact with the insulating layer 2, 3, 4, prevent the peripheral corner portion 5A from causing damage to the insulating layer 2, 3, 4 and thereby possible to suppress the occurrence of a crack in the insulating layer 2, 3, 4.

(1b) In the present embodiment, the rounded corner portion 5A is formed from the front surface to the side surface of the wiring layer 5 in the thickness direction within the range of 30% or less of the average thickness of the wiring layer 5. It is thus possible to effectively prevent the wiring layer 5 (corner portion 5A) from causing damage to the insulating layer 2, 3, 5 adjacent thereto, while suppressing a deterioration in the strength of the wiring layer 5.

(1c) Furthermore, each of the wiring layers 5 is not fixed to any of the insulating layers 2, 3, 4 adjacent thereto in the present embodiment. When the wiring layers 5 and the insulating layers 2, 3, 4 expand or contract in accordance with temperature changes, there arises a difference in deformation amount between the wiring layers 5 and the insulating layers 2, 3, 4 due to a difference in thermal expansion coefficient. However, such a deformation amount difference can be absorbed by individual displacements of the wiring layers 5 and the insulating layers 2, 3, 4. It is possible by such displacement to reduce stress caused between the insulating layers 2, 3, 4 and the wiring layers 5 and suppress the occurrence of a defect such as crack in the insulating layers 2, 3, 4.

(1d) As the insulating layers 2, 3, 4 contain a ceramic material as a main component, it is possible to improve the flatness of the insulating layers 2, 3, 4 so that the wiring layers 5 can be arranged at high density on the insulating layers 2, 3, 4. It is also possible by the use of such a ceramic material to ensure the high insulation properties of the insulating layers 2, 3, 4 and thereby enable reliable insulation between the wiring layers 5 even in the case where a relatively large current flows though the wiring layers 5.

### 2. Modification Examples

Although the present invention has been described with reference to the above embodiment, the above embodiment is intended to facilitate understanding of the present invention and is not intended to limit the present invention thereto. Various changes and modifications can be made to the above embodiment without departing from the scope of the present invention.

(2a) The above-mentioned configuration of the wiring layers 5 in the wiring board 1 is merely one example. As a modification example of the wiring board 1, it is feasible to provide a wiring-board 11 by modifying the configuration of the wiring layers 5 such that, when each of the wiring layers 5 is viewed in cross section in parallel to the thickness direction, all of corner portions 5A and 5B of the cross section are rounded as shown in FIG. 4. In this configuration, it is possible to simultaneously prevent the wiring layer 5 from causing damage two of the insulating layers 2, 3, 4 adjacent thereto.

Further, the entire peripheral edge of the wiring layer 5 is not necessarily rounded. As long as at least a part of the peripheral edge of the wiring layer 5 is rounded, it is possible to suppress the wiring layer 5 from causing damage to the insulating layer 2, 3, 4.

(2b) The range of formation of the rounded corner portion 5A in the thickness direction is not particularly limited. In the wiring board 1, the rounded corner portion 5A is not necessarily formed within the range of 30% or less of the average thickness of the wiring layer 5.

(2c) In the wiring board 1, the plurality of wiring layers 5 may be partially or entirely fixed to the insulating layers 2, 3, 4 adjacent thereto by a metal brazing material or solder material. The connection conductors 7 may be fixed to the insulating layers 4. In other words, each of the wiring layers 5 may have two areas: fixed and non-fixed areas and does not necessarily have a non-fixed area.

(2d) The above-mentioned configuration of the connection conductor 7 in the wiring board 1 is merely one example. In place of using the metal granular body 7A, it is feasible to arrange a solid metal block body (such as column-like body, plate-like body, foil-like body) or a spherical metal body in the through hole 3A of the insulating layer 3 and join the metal body to the wiring layers 5 though the joint parts. It is alternatively feasible to arrange a metal rod through the plurality of wiring layers 5 in the thickness direction and join the metal rod to the wiring layers 5 through junction parts.

(2e) The material of the insulating layers 2, 3, 4 is not limited to the ceramic material. The insulating layers 2, 3, 4 may each alternatively contain a resin material, glass material or the like as the main component.

(2f) The wiring board 1 is suitably applicable to a planar transformer. In the case of the planar transformer with the wiring board 1, the plurality of wiring layers 5 may respectively have coil wiring patterns at peripheral portions of the adjacent insulating layers 2, 3, 4. In this case, core insertion holes for insertion of a magnetic core (such as ferrite) may be formed in center portions of the insulating layers 2, 3, 4 so as to pass through the coil wiring patterns.

(2g) In the wiring board 1, the plurality of insulating layers 2, 3, 4 are illustrated as having the same thickness; and the plurality of wiring layers 5 are illustrated as having the same thickness. However, the plurality of insulating layers 2, 3, 4 may be of different thicknesses; and the plurality of wiring layers 5 may be of different thicknesses. Further, the plurality of wiring layers 5 may be of different occupation areas.

(2h) It is feasible in the above embodiment to divide the function of one component among a plurality of components or combine the functions of a plurality of components into one. Any of the technical features of the above embodiment may be omitted, replaced or combined as appropriate. All of embodiments and modifications derived from the technical scope of the following claims are included in the present invention.

The entire contents of Japanese Patent Application No. 2017-177556 (filed on Sep. 15, 2017) are herein incorporated by reference.

What is claimed is:

1. A wiring board, comprising:
a plurality of insulating layers; and
at least one wiring layer each located between adjacent two of the plurality of insulating layers,
wherein, when a cross section of the at least one wiring layer is taken in parallel to a thickness direction, at least one corner portion of the cross section of the at least one wiring layer is rounded.

2. The wiring board according to claim 1,
wherein, in the cross section, a dimension of the rounded corner portion in the thickness direction is 30% or less of an average thickness of the at least one wiring layer.

3. The wiring board according to claim 1,
wherein all of corner portions of the cross section of the at least one 3 wiring layer are rounded.

4. The wiring board according to claim 1,
wherein the at least one wiring layer include a plurality of wiring layers, and
wherein the plurality of insulating layers and the plurality of wiring layers are alternately laminated in the thickness direction.

5. The wiring board according to claim 1,
wherein each of the at least one wiring layer is not fixed to any of the plurality of insulating layers adjacent thereto.

6. The wiring board according to claim 1,
wherein the plurality of insulating layers contain a ceramic material as a main component.

7. A planar transformer comprising the wiring board according to claim 1.
